(19) United States
(12) Patent Application Publication
(10) Pub. No.: US 2023/0418164 A1
(43) Pub. Date: Dec. 28, 2023

(54) EDGE EXPOSURE APPARATUS, METHOD OF MAKING AND USING THE SAME

(71) Applicant: Merritt Conner, Colorado Springs, CO (US)

(72) Inventor: Merritt Conner, Colorado Springs, CO (US)

(21) Appl. No.: 18/214,455

(22) Filed: Jun. 26, 2023

Related U.S. Application Data
(60) Provisional application No. 63/355,913, filed on Jun. 27, 2022.

(51) Int. Cl. G03F 7/00

(52) U.S. Cl. CPC G03F 7/70141; G03F 7/7005; G03F 7/70016

(57) ABSTRACT

An LED wafer edge exposure apparatus may be used to emit light on a workpiece (such as a silicon wafer with a photoresist layer) during a manufacturing process (such as an edge exposure process or photolithography process) of semiconductors (such as computer chips). The LED wafer edge exposure apparatus may be created by exchanging an existing light source, e.g., a mercury vapor lamp, with a replacement light source, e.g., an LED light source in a high energy wafer edge exposure apparatus.

### CROSS REFERENCE TO RELATED APPLICATION

This application claims the benefit of U.S. Provisional Application No. 63/355,913, filed Jun. 27, 2022, which is fully incorporated herein by reference as if fully set forth herein.

### BACKGROUND OF THE INVENTION

### Field of the Invention

The present invention generally relates to an edge exposure apparatus, a method of making and using the same, and more particularly to a method and system of replacing a mercury vapor (Hg) light source in an existing tool with an LED light source by emulating mechanical commands meant for the original mercury vapor light source with non-mechanical software emulation commands to the replacement LED light source.

### SUMMARY OF THE INVENTION

Accordingly, the invention is directed to an edge exposure apparatus, method of making and using the same that substantially obviates one or more of the problems due to limitations and disadvantages of the related art. The LED wafer edge exposure apparatus may be used to emit light on a workpiece (such as a silicon wafer with a photoresist layer) during a manufacturing process (such as an edge exposure process or photolithography process) of semiconductors (such as computer chips).

An advantage of the invention is to provide a system that allows for retrofitting or exchanging an existing light source, e.g., a mercury vapor lamp, with a replacement light source, e.g., an LED light source.

Advantages of the invention are to provide a system that is less expensive to purchase, less expensive to operate and less hazardous to operate than existing edge exposure apparatuses.

In another aspect of the present invention, a method of operating a retrofit high energy edge exposure unit for edge exposure includes proving a low energy retrofit edge exposure unit as described in any of the embodiments or disclosure described herein. The method further includes receiving a workpiece covered by a photosensitive layer and exposing an edge portion of the photosensitive layer to radiation generated by the low energy retrofit edge exposure unit.

In still yet another aspect of the invention, the method includes removing a first light source, possibly a mercury vapor lamp light source, and replacing the first light source with a second light source, possibly an LED light source.

In yet another aspect of the invention, a replacement LED module may emulate an original high energy module using code. The emulation may include replacing mechanical commands intended for the original high energy module with non-mechanical commands that perform similar functions with the replacement LED module.

In yet another aspect of the invention, a host controller, which may be part of an original edge exposure tool and thus configured to control a mercury vapor lamp light source, may communicate signals intended for the mercury vapor lamp light source, but received by an emulator on a replacement LED module, which may convert the mercury vapor lamp light commands into commands for an LED light source.

In still another embodiment, a host controller, which may be part of an original edge exposure tool, may communicate mechanical commands intended for a diaphragm, filter and/or shutter used by the original high energy light source and an emulator may receive the mechanical commands and emulate the mechanical commands as non-mechanical commands using software and an LED light source.

In another aspect of the present invention, the apparatus is an edge-exposure tool as described herein. A method of using the tool includes providing a workpiece table configured to support a workpiece covered by a photosensitive layer, and a retrofit edge exposure light source and operating the retrofit edge exposure light source at least partially on the photosensitive layer.

In one embodiment, an aspect of the invention is directed towards a method for retrofitting an existing high energy edge exposure unit. The method includes removing an existing high energy light source from the existing high energy edge exposure unit and arranging a low energy light source in the existing high energy edge exposure unit.

In another embodiment, an aspect of the invention is directed towards a method of operating a retrofit high energy edge exposure unit for edge exposure. The method includes proving a low energy retrofit edge exposure unit, receiving a workpiece covered by a photosensitive layer, and exposing an edge portion of the photosensitive layer to radiation generated by the low energy retrofit edge exposure unit.

In still yet another embodiment, an aspect of the invention is directed towards an edge-exposure tool including a workpiece table configured to support a workpiece covered by a photosensitive layer, and a retrofit edge exposure light source configured to radiate the photosensitive layer.

In yet another embodiment, an aspect of the invention is directed towards a method for edge exposure including receiving a workpiece covered by a photosensitive layer, and exposing an edge portion of the photosensitive layer with radiation from a retrofit unit.

In another embodiment, an aspect of the invention is directed towards a method for operating an LED wafer edge exposure apparatus including receiving by an LED module, comprising an emulator and an LED light source, a command from a host controller to turn a lamp on, and verifying by the emulator that the LED light source is operational in response to the received command to turn the lamp on.

In still yet another embodiment, an aspect of the invention is directed towards a method for operating an LED wafer edge exposure apparatus including receiving by an LED module, comprising an emulator and an LED light source, a command from a host controller to turn a lamp off, and powering down by the emulator the LED light source in response to the received command to turn the lamp off.

In yet another embodiment, an aspect of the invention is directed towards a method for operating an LED wafer edge exposure apparatus including receiving by an LED module including an emulator and an LED light source, a command from a host controller to open a diaphragm, and increasing incrementally by the emulator a power by a predetermined amount to the LED light source in response to the received command to open the diaphragm.

In yet another embodiment, an aspect of the invention is directed towards a method for operating an LED wafer edge exposure apparatus including receiving by an LED module, comprising an emulator and an LED light source, a command from a host controller to close a diaphragm, and decreasing incrementally by the emulator a power by a predetermined amount to the LED light source in response to the received command to close the diaphragm.

In another embodiment, an aspect of the invention is directed towards a method for operating an LED wafer edge exposure apparatus including receiving by an LED module, comprising an emulator and an LED light source, a command from a host controller to insert a filter, and decreasing a power by the emulator by a predetermined percentage to the LED light source in response to the received command to insert the filter.

In still another embodiment, an aspect of the invention is directed towards a method for operating an LED wafer edge exposure apparatus including receiving by an LED module, comprising an emulator and an LED light source, a command from a host controller to remove a filter, and increasing a power by the emulator by a predetermined percentage to the LED light source in response to the received command to remove the filter.

In yet another embodiment, an aspect of the invention is directed towards a method for operating an LED wafer edge exposure apparatus including receiving by an LED module, including an emulator and an LED light source, a command from a host controller to close a shutter. The method further includes disabling, by the emulator, the LED light source from emitting light to a workpiece in response to the received command to close the shutter.

In another embodiment, an aspect of the invention is directed towards a method for operating an LED wafer edge exposure apparatus including receiving by an LED module, including an emulator and an LED light source, a command from a host controller to open a shutter. The method also includes enabling, by the emulator, the LED light source to emit light to a workpiece in response to the received command to open the shutter.

In still another embodiment, an aspect of the invention is directed towards a non-transitory computer-readable medium storing instructions executable by at least one electronic processor to perform a set of functions. The set of functions includes receiving a first data input by an emulator from a host controller, where the first data input comprises information indicative of a command to turn a lamp on in a high energy (HE) wafer edge exposure apparatus. The set of functions also includes generating a first data output based on a verification by the emulator that a light emitting diode (LED) light source in an LED wafer edge exposure apparatus is operational and outputting the first data output by the emulator to the host controller indicating that the lamp is on, when in fact no lamp was turned on in the LED wafer edge exposure apparatus.

In yet still another embodiment, an aspect of the invention is directed towards a non-transitory computer-readable medium storing instructions executable by at least one electronic processor to perform a set of functions. The functions include receiving a first data input by an Emulator from a Host Controller, where the first data input comprises information indicative of a command to open a diaphragm in a High Energy (HE) wafer edge exposure apparatus, and increasing by the Emulator a power to the LED light source in an LED wafer edge exposure apparatus in response to the received command from the Host Controller to open the diaphragm.

In still another embodiment, an aspect of the invention is directed towards a non-transitory computer-readable medium storing instructions executable by at least one electronic processor to perform a set of functions including receiving a first data input by an Emulator from a Host Controller, where the first data input comprises information indicative of a command to insert a filter in a High Energy (HE) wafer edge exposure apparatus, and decreasing by the Emulator by 50% a power to an LED light source in an LED wafer edge exposure apparatus in response to the received command from the Host Controller to close the diaphragm.

In another embodiment, an aspect of the invention is directed towards a non-transitory computer-readable medium storing instructions executable by at least one electronic processor to perform a set of functions. The set of functions includes receiving a first data input by an emulator from a host controller, where the first data input comprises information indicative of a command to open a shutter in a high energy (HE) wafer edge exposure apparatus, and enabling an LED light source to emit light to a workpiece in an LED wafer edge exposure apparatus in response to the received command from the Host Controller to open the shutter.

This Summary section is neither intended to be, nor should be, construed as being representative of the full extent and scope of the present disclosure. Additional benefits, features and embodiments of the present disclosure are set forth in the attached figures and in the description hereinbelow, and as described by the claims. Accordingly, it should be understood that this Summary section may not contain all of the aspects and embodiments claimed herein.

Additional features and advantages of the invention will be set forth in the description which follows, and in part, will be apparent from the description, or may be learned by practice of the invention. The objectives and other advantages of the invention will be realized and attained by the structure, particularly pointed out in the written description and claims hereof as well as the appended drawings.

Additionally, the disclosure herein is not meant to be limiting or restrictive in any manner. Moreover, the present disclosure is intended to provide an understanding to those of ordinary skill in the art of one or more representative embodiments supporting the claims. Thus, it is important that the claims be regarded as having a scope including constructions of various features of the present disclosure insofar as they do not depart from the scope of the methods and apparatuses consistent with the present disclosure (including the originally filed claims). Moreover, the present disclosure is intended to encompass and include obvious improvements and modifications of the present disclosure.

### BRIEF DESCRIPTION OF THE DRAWINGS

The accompanying drawings, which are included to provide a further understanding of the invention and are incorporated in and constitute a part of this specification, illustrate embodiments of the invention and, together with a description serve to explain the principles of the invention.

The drawings are embedded and described herein.

In the drawings:

FIG. 1 illustrates an exemplary flowchart for code for an LED module to emulate a mercury lamp module according to an embodiment of the invention.

FIG. 2 illustrates an exemplary diagram of an apparatus according to another embodiment of the invention.

FIG. 3 illustrates an exemplary diagram of FIG. 2 according to another aspect of the invention.

FIG. 4 is a graphical representation of intensity versus wavelength of a conventional mercury lamp.

FIG. 5 is a graphical representation of intensity versus wavelength of an LED lamp according to an embodiment of the invention.

FIG. 6 illustrates an exemplary flowchart for de-installing a light source module according to an embodiment of the invention.

FIG. 7 illustrates an exemplary flowchart for installing a light source module according to an embodiment of the invention.

FIG. 8 illustrates an exemplary flowchart for using an apparatus according to an embodiment of the invention.

For simplicity and clarity of illustration, the drawing figures illustrate the general manner of construction, and descriptions and details of well-known features and techniques may be omitted to avoid unnecessarily obscuring the present disclosure. Additionally, elements in the drawing figures are not necessarily drawn to scale. For example, the dimensions of some of the elements in the figures may be exaggerated relative to other elements to help improve understanding of embodiments of the present disclosure. The same reference numerals in different figures denote the same elements.

### DETAILED DESCRIPTION OF THE ILLUSTRATED EMBODIMENTS

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “computer-readable medium,” as used herein, refers to any tangible storage and/or transmission medium that participate in providing instructions to a processor for execution. Such a medium may take many forms, including but not limited to, non-volatile media, volatile media, and transmission media. Non-volatile media includes, for example, NVRAM, or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a CD-ROM, any other optical medium, punch cards, paper tape, any other physical medium with patterns of holes, a RAM, a PROM, an EPROM, a FLASH-EPROM, a solid state medium like a memory card, any other memory chip or cartridge, a carrier wave as described hereinafter, or any other medium from which a computer can read. A digital file attachment to an e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

The term “module,” as used herein, refers to any known or later developed hardware, software, firmware, artificial intelligence, fuzzy logic, or combination of hardware and software that is capable of performing the functionality associated with that element.

The terms “determine,” “calculate,” and “compute,” and variations thereof, as used herein, are used interchangeably and include any type of methodology, process, mathematical operation or technique.

Functional units described in this specification and figures may be labeled as modules, or outputs in order to more particularly emphasize their structural features. A module and/or output may be implemented as hardware, e.g., comprising circuits, gate arrays, off-the-shelf semiconductors such as logic chips, transistors, or other discrete components. They may be fabricated with Very-Large-Scale Integration (VLSI) techniques. A module and/or output may also be implemented in programmable hardware such as field programmable gate arrays, programmable array logic, programmable logic devices or the like. Modules may also be implemented in software for execution by various types of processors. In addition, the modules may be implemented as a combination of hardware and software in one embodiment.

An identified module of programmable or executable code may, for instance, include one or more physical or logical blocks of computer instructions that may, for instance, be organized as an object, procedure, or function. Components of a module need not necessarily be physically located together but may include disparate instructions stored in different locations which, when joined logically together, include the module and achieve the stated function for the module. The different locations may be performed on a network, device, server, and combinations of one or more of the same. A module and/or a program of executable code may be a single instruction, or many instructions, and may even be distributed over several different code segments, among different programs, and across several memory devices. Similarly, data or input for the execution of such modules may be identified and illustrated herein as being an encoding of the modules, or being within modules, and may be embodied in any suitable form and organized within any suitable type of data structure.

In one embodiment, the system, components and/or modules discussed herein may include one or more of the following: a server or other computing system including a processor for processing digital data, memory coupled to the processor for storing digital data, an input digitizer coupled to the processor for inputting digital data, an application program stored in one or more machine data memories and accessible by the processor for directing processing of digital data by the processor, a display device coupled to the processor and memory for displaying information derived from digital data processed by the processor, and a plurality of databases or data management systems.

In one embodiment, functional block components, screen shots, user interaction descriptions, optional selections, various processing steps, and the like are implemented with the system. It should be appreciated that such descriptions may be realized by any number of hardware and/or software components configured to perform the functions described. Accordingly, to implement such descriptions, various integrated circuit components, e.g., memory elements, processing elements, logic elements, look-up tables, input-output devices, displays and the like may be used, which may carry out a variety of functions under the control of one or more microprocessors or other control devices.

In one embodiment, software elements may be implemented with any programming, scripting language, and/or software development environment, e.g., Fortran, C, C++, C #, COBOL, Apache Tomcat, Spring Roo, Web Logic, Web Sphere, assembler, PERL, Visual Basic, SQL, SQL Stored Procedures, AJAX, extensible markup language (XML), Flex, Flash, Java, .Net and the like. Moreover, the various functionality in the embodiments may be implemented with any combination of data structures, objects, processes, routines or other programming elements.

In one embodiment, any number of conventional techniques for data transmission, signaling, data processing, network control, and the like as one skilled in the art will understand may be used. Additionally, many of the functional units and/or modules, e.g., shown in the figures, may be described as being “in communication” with other functional units and/or modules. Being “in communication” refers to any manner and/or way in which functional units and/or modules, such as, but not limited to, input/output devices, computers, laptop computers, PDAs, mobile devices, smart phones, modules, and other types of hardware and/or software may be in communication with each other. Some non-limiting examples include communicating, sending and/or receiving data via a network, a wireless network, software, instructions, circuitry, phone lines, Internet lines, fiber optic lines, satellite signals, electric signals, electrical and magnetic fields and/or pulses, and/or the like and combinations of the same.

In one embodiment, the edge exposure apparatus, method of making and using the same to enable any person skilled in the art to make and use the disclosed subject matter in the context of one or more particular implementations. Various modifications, alterations, and permutations of the disclosed implementations can be made and will be readily apparent to those skilled in the art, and the general principles defined may be applied to other implementations and applications without departing from the scope of the disclosure.

The present disclosure is not intended to be limited to the described or illustrated implementations but to be accorded the widest scope consistent with the described principles and features.

In order to appreciate the present disclosure more fully and to provide additional related features, each of the following references (1)-(3) are fully incorporated herein by reference in their entireties and for the teachings as follows:
(1) U.S. Pat. No. 5,811,211 issued to Tanka, et al., which discloses a photosensitive substrate is exposed with both a peripheral edge exposure apparatus which exposes the peripheral portion of the photosensitive substrate in a specified exposure width and a pattern exposure apparatus which transfers a scale pattern to the photosensitive substrate so that a dimension from the outer periphery of the photosensitive substrate is known. The accuracy (offset quantity) of the exposure width of the peripheral edge exposure apparatus is evaluated by reading out the resist image of the scale pattern which appears on the substrate after development.
(2) U.S. Pat. No. 7,573,054 issued to Iwashita, et al., which discloses a first and a second optical path forming member arranged within a path of light beams from a light source; a first mounting table provided such that the edge portion of the substrate is located within an application region of the light beams from an outlet side of the first optical path forming member, and a second mounting table provided such that the edge portion of the substrate is located within an application region of the light beams from an outlet side of the second optical path forming member, each of the mounting tables being configured to be rotatable about a vertical axis while mounting the substrate thereon; and a light blocking means for blocking application of light from each of the first and second optical path forming members. A common light source can be used to perform edge exposure for the substrates on the first and second mounting tables, for example, at the same time, so that a high processing ability can be offered and an increase in size of the apparatus can be prevented.
(3) U.S. Pat. No. 10,295,909, which discloses various embodiments of the present application are directed towards an edge-exposure tool with a light emitting diode (LED), as well as a method for edge exposure using a LED. In some embodiments, the edge-exposure tool comprises a process chamber, a workpiece table, a LED, and a controller. The workpiece table is in the process chamber and is configured to support a workpiece covered by a photosensitive layer. The LED is in the process chamber and is configured to emit radiation towards the workpiece. A controller is configured to control the LED to expose an edge portion of the photosensitive layer, but not a center portion of the photosensitive layer, to the radiation emitted by the LED. The edge portion of the photosensitive layer extends along an edge of the workpiece in a closed path to enclose the center portion of the photosensitive layer.

The retrofit low energy edge exposure apparatus described herein can be utilized in any of the exposure apparatus, e.g., the edge exposure apparatus described in U.S. Pat. Nos. 5,811,211, 7,573,054, and 10,295,909, each of which is hereby incorporated by reference in its entirety and each of which is also incorporated for teaching an edge exposure apparatus.

In one embodiment, that apparatus is configured to allow for quick and simple integration into a variety of semiconductor manufacturing tools that would benefit from an LED Wafer Edge Exposure (WEE) process light source, e.g., the LED module 202. The conventional mercury (Hg) vapor LED Wafer Edge Exposure (WEE) process light is known in the art.

An embodiment of the invention is directed towards use of a lower power light apparatus and/or retrofit apparatus that is configured to plug directly into an existing mercury vapor unit as a direct replacement.

Reference will now be made in detail to an embodiment of the present invention, an example of which is illustrated in the accompanying drawings.

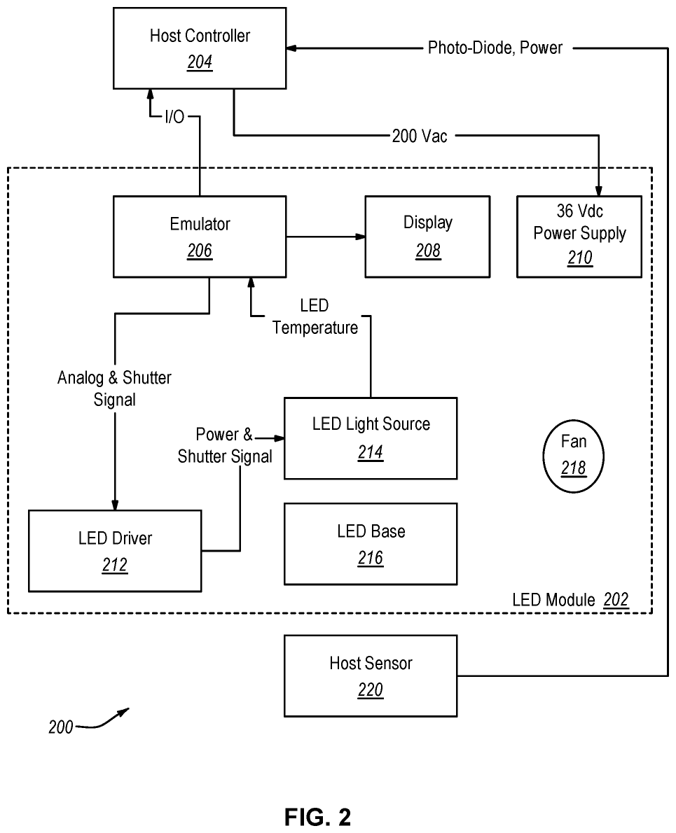

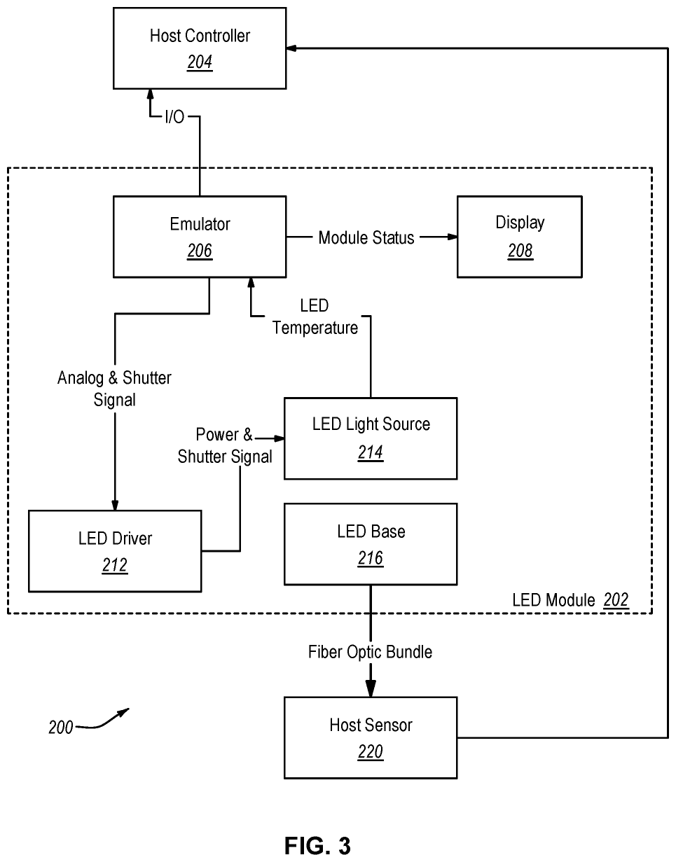

FIGS. 2 and 3 illustrate exemplary diagrams of an apparatus according to an embodiment of the invention. An embodiment of the invention is directed towards an integrated signal emulator 206 configured to control and operate an LED module 202. The emulator 206 is configured to interpret the discrete I/O signals utilized by the host controller 204 of the host tool to control a conventional mercury (Hg) vapor light source, and the emulator 206 converts the signals into signals that can be used by the LED module 202 of embodiments herein and host tool as described herein. The emulator 206 also includes a controller or is in communication with a controller or microcontroller.

A wafer edge exposure (WEE) apparatus 200 is configured to be retrofitted by replacing a conventional high energy light source, e.g., a conventional high energy mercury (Hg) vapor light sources used in semiconductor apparatuses with an LED module 202 that includes a low energy LED light source 214 to create an LED WEE apparatus 200. The LED module 202 is configured as a low power and less expensive alternative to existing light sources, e.g., high energy mercury (Hg) vapor light source and unit. The LED module 202 is configured as a retrofit apparatus, kit apparatus and/or as a direct replacement apparatus. Optionally, the LED module 202 is configured to directly replace the high energy light source of conventional semiconductor tools, e.g., semiconductor wafer edge exposure apparatus. The LED module 202 as described herein is a direct replacement that requires little to no additional features. In some embodiments, new recipes may be created and used so that the host controller 204 may work properly with the replacement LED module 202. That is the LED module 202 is configured as a plug and play module where the LED module 202 can be placed directly into the existing high energy light source, e.g., mercury (Hg) vapor light source, location as a direct replacement.

The lower power LED light source 214 may include an array of LEDs that may emit light in predetermined selection wavelengths, e.g., narrow wavelengths. In preferred embodiments, the types of LEDs selected to be used as part of the LED light source 214 are LEDs that emit light at wavelengths and energies that are effective and desirable to be used with whichever photosensitive coatings will be used on workpieces processed by the WEE apparatus 200.

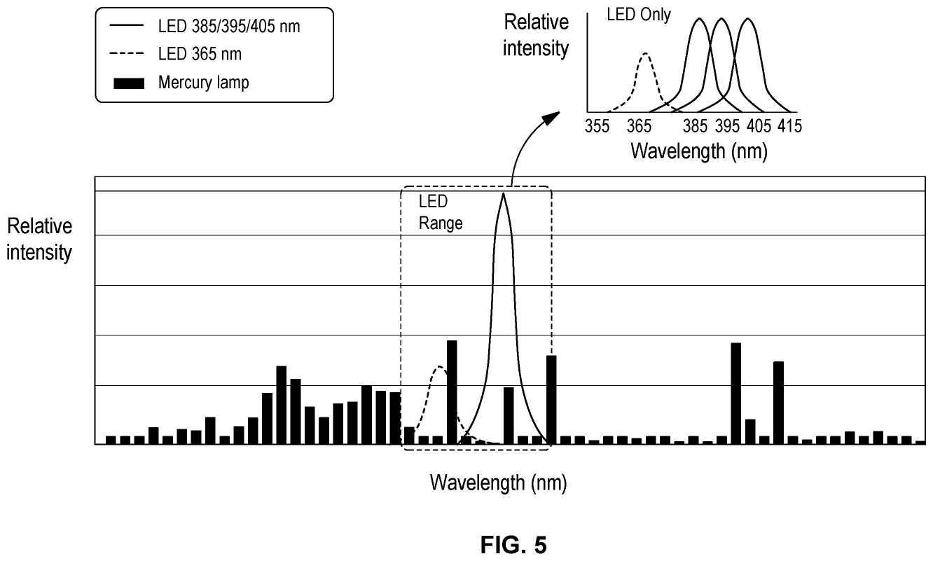

Referring to FIG. 5, in a specific example of one or more LEDs that may be used, that is, the wavelengths of the LED light source 214 may be in a range from about 255 nm to about the 415 nm or greater. In a preferred embodiment, a wavelength of about 255 nm (DUV) and about 365 nm (i-line) can be utilized and these wavelengths are known in the semiconductor industry.

The LED light source 214 is much more cost effective as compared to the conventional mercury (Hg) lamp sources. In some systems, the LED light source may be cheaper by an order of magnitude. The LED light source 214 provides a more stable and precise wavelengths of light at a much lower energy cost when compared to a mercury (Hg) light source and the LED light source 214 is less dangerous to people. In addition, the conventional mercury (Hg) lamp light sources also require a considerably larger footprint for their power sources and control mechanisms. As a non-limiting specific example, a conventional light source may have a footprint area of about 60,000 cc while the LED light source may have a footprint area of about 6,600 cc.

A retrofit package or kit, that includes the LED module 202, may be used to retrofit the high energy WEE apparatus into a low energy WEE apparatus 200.

In a preferred embodiment, the host controller 204 includes a printed circuit board (PCB) programmed to specifically work within an 8 inch Photo lithography process tool (ACTS), a 12 inch Photo lithography Process tool (ACT12), or adaptation for other tool types under development.

The LED module 202 may also include a display 208, e.g., such as digital display, organic light emitting diode (OLED) display, light emitting diode (LED) display, liquid crystal display (LCD), thin film transistor (TFT) display, active-matrix organic light-emitting diode (AMOLED) display, super AMOLED display and or digital displays as known in the art. The display 208 may be configured to show interface functions, current source state, source hours, power level and other characteristics as described herein of the LED module 202. The LED module 202 may be configured to connect directly to the host tool thereby requiring minimal modifications to the host tool. In some embodiments, new recipes may be needed to be created and used to control the LED module 202 during workpiece processing. In addition, some embodiments may require a new host sensor 220 that is better at detecting light from LED sources.

The LED module 202 may further include a power supply 210 configured to power the LED driver 212, the LED light source 214 and associated electronics. In a preferred embodiment, the power supply 210 receives 200 Volt (V) alternating current (AC) by the host controller 204 and supplies 36 volt (V) direct current (DC).

The emulator 206 is a uniquely designed PCB configured to capture host controller 204 signals. The emulator 206 is configured to utilize software specifically written to receive signals from the host tool's original host controller 204 and provide functionally equivalent commands to an LED light source 214 that mimic the signals from the host tool. The emulator 206 takes the mechanical commands from the host controller 204 intended to be used with a mercury (Hg) vaper lamp module and performs the mechanical commands in a non-mechanical way using the LED light source 214.

The emulator 206 may mimic the operations of a mechanical shutter previously used by the mercury light source with a virtual shutter operated by the embedded software. As a non-limiting example, the emulator 206 may either apply or remove power to the LED light source 214 to simulate the actions of a shutter opening or closing.

The emulator 206 may control an LED driver 212 that is configured to control the LED light source 214 in ways that mimic the mechanical light controls (filter, diaphragm, and shutter) of the mercury light source.

In a preferred embodiment, the LED light source 214 includes a quick-change base, e.g., an LED base 216, that is configured to allow for rapid light source changes without waiting for the system to cool down.

One or more LEDs that form an LED array may be selected for the LED light source 214 that match the wavelength of light required by the host tool process. The LED light source 214 may include one or more LED that have a wavelength in any desired range as described herein. As a non-limiting example, the LED light source 214 may emit light in a range from about 255 nm to about 415 nm or greater with a radiant flux at the surface of the substrate to be exposed of about 50 mW/cm² or greater. Of course other wavelengths are possible, e.g., less than 255 nm. The LED light source 214 in other embodiments may select different types of LEDs that output light in any desired spectrum that works well with the photosensitive coating being worked with. The LED light source 214 may include a heat sink and may be arranged on an LED base 216. The LED base 216 may be configured for either optic or liquid optic light transmission.

Referring to FIG. 2, the WEE apparatus 200 is generally depicted with reference to number 200. In this embodiment, the WEE apparatus 200 includes an LED module 202 and the LED module 202 includes an emulator 206. The host controller 204 may receive inputs from the host sensor 220 and the emulator 206. The host sensor 220 is configured to optimally measure the intensity of the individual wavelength of light emitted by the specific LED in operation. The LED module 202 includes an emulator 206 that is in digital communication with the host controller 204 and the display 208. The display 208 may be a digital display as discussed herein and the display 208 may output information regarding the WEE apparatus 200 to a user, e.g., LED source hours, power level, interface functions, LED temperature, etc.

The LED light source 214 may be configured to output information indicative of an LED light source temperature to the emulator 206. The host controller may be in communication with the power supply 210 and the emulator 206. The LED driver 212 is on a PCB and may be configured to mimic the mechanical actions of a shutter, filter and/or diaphragm using software to control the LED light source 214 based on information received from the emulator 206. For example, the emulator 206 may tell the LED driver 212 when the LED light source should emit light and at what power level and report back to the host controller 204 that the light is emitting. The WEE apparatus 200 may further include an LED base 216 that may be configured to allow for a simple replacement of a worn out, broken or change of wavelength of a LED light source 214. The LED base 216 may be a quick change LED base 216. The cooling fan 218 may be configured to maintain a stable diode operating temperature at or above ambient temperature.

Referring to FIG. 3, in operation the host sensor 220 may detect a light intensity or power and communicate that data to the host controller 204. The host sensor 220 may be configured to optimally detect the lower light energy levels characteristic of the monochromatic light emitted by the LED module. The emulator 206 may be in communication with the display 208 to inform the display what information should be displayed by the display 208. The LED module 214 may be in communication with the fan 218 to control the temperature of the LED light source 214.

This embodiment of the invention is directed towards a wafer edge exposure process and an LED WEE apparatus 200. The LED WEE apparatus 200 may be able to store a plurality of recipes, where each recipe corresponds to a particular workpiece that may be processed by the LED WEE apparatus 200. The LED WEE apparatus may read a stored recipe that corresponds to a current workpiece to be processed by the LED WEE apparatus 200.

The process includes a host controller 204 receiving and/or requesting the recipe for the current workpiece which may include, as non-limiting examples, an intensity or power of light and a duration for the light from the LED light source 214. The intensity or power of light and the duration for the light from the LED light source 214 may be empirically found by trying different combinations for different photosensitive or photoresist coatings and workpieces that may be processed by the LED WEE apparatus 200 and saving as recipes the most efficient combinations of powers and durations.

In one embodiment, the LED light source 214 may produces a light with a wavelength between about 255 nm and about 265 nm with an intensity of about 50 mW/cm². The LED WEE apparatus 200 may utilize process variables in its operation, including time and intensity, and others as known in the art to determine an optimal energy output required by the specified process.

Optionally and/or alternatively, in one embodiment, the LED WEE apparatus 200 may be manually configured with process variables by a user manually inputting the process variables into the LED WEE apparatus 200. Optionally, the LED WEE apparatus 200 may be configured to receive and/or obtain preexisting light power setting stored in the LED WEE apparatus 200.

In one embodiment, if the light intensity from the LED light source 214, as determined by the host sensor 220, is not in specification, the host controller 204 may send either positive or negative pulse counts to the emulator 206 that instruct the emulator 206 to either slightly open or slightly close a diaphragm. The emulator 206 (not having a mechanical diaphragm to open or close) may simulate the actions of a diaphragm opening and closing by either increasing (opening the diaphragm) or decreasing (closing the diaphragm) the light intensity from the LED light source 214 by some predetermined amount. The emulator 206 may be configured to translate the one or more host pulse counts from the host controller 204 into an analog signal which may be transmitted to the LED driver 212. The LED driver 212 may use the analog signal to adjust the light intensity of the LED light source 214. The process of adjusting the light intensity from the LED light source 214 may be repeated until the host controller 204 determines the light intensity from the LED light source 214 is within a desired specification.

The host controller 204 may transmit a shutter close command to the emulator 206 when the host controller 204 desires zero light intensity from the LED light source 214. The emulator 206 (not having a mechanical shutter to close) may transmit a signal to the LED driver 212 which simulates a shutter being closed by the LED driver 212 stopping all power to the LED light source 214. The host controller 204 may transmit a shutter open command to the emulator 206 when the host controller 204 desires a dose of light from the LED light source 214 to be radiated to a workpiece. The emulator 206 may transmit a signal to the LED driver 212 that directs the LED driver 212 to enable the LED light source 214 to emit light to the workpiece.

The host controller 204 may transmit a filter in command to the emulator 206 when the host controller 204 wants to reduce a current light level intensity setting from the LED light source 214. The simulated filter may reduce the light intensity by any desired amount. In a preferred embodiment, a filter in command from the host controller 204 may reduce a light intensity from the LED light source 214 by 50%. The emulator 206 (not having a mechanical filter to insert) may transmit a signal to the LED driver 212 to reduce the power to the LED light source 214 by 50%. A filter out command from the host controller 204 may be used to restore the LED light source 214, basically by doubling the power to the LED light source 214.

In one embodiment, software is utilized which accepts existing signals for the HOST (TEL ACTS) and converts them to new signals for the LED module as shown in Table 1 as follows:

TABLE 1

| | HOST (TEL ACT8) | LED Module | |
|---|---|---|---|
| | Existing Signal | New Signal | |
| Mechanical | Lamp On/Off | LED Module | Software |
| Function | | Ready | Emulation |
| Mechanical | Shutter In/Out | LED Emit Light | Software |
| Function | | | Emulation |
| Mechanical | Filter In/Out | CUT LED Pwr | Software |
| Function | | 50% | Emulation |
| Mechanical | Diaphragm Open | LED Intensity Up | Software |
| Function | | | Emulation |
| Mechanical | Diaphragm Close | LED Intensity | Software |
| Function | | Down | Emulation |

As shown in Table 1 the existing mechanical function signal “Lamp On” that was sent from the HOST (TEL ACT8), e.g. host controller 204, may now be interpreted by the emulator 206 in the LED module 202 as the new signal LED module ready. The existing mechanical function signal “Lamp Off” that was sent from the host controller 204 may now be interpreted by the emulator 206 in the LED module 202 as the new signal LED module Not Ready.

The existing mechanical function signal “Shutter In” that was sent from the HOST (TEL ACT8), e.g., host controller 204, may now be interpreted by the emulator 206 in the LED module 202 as the new signal LED block light causing the LED light source 214 to turn off. The existing mechanical function signal “Shutter Out” that was sent from the HOST (TEL ACT8), e.g., host controller 204, may now be interpreted by the emulator 206 in the LED module 202 as the new signal LED emit light causing the LED light source to turn on.

The existing mechanical function signal “Filter In” that was sent from the HOST (TEL ACT8), e.g., host controller 204, may now be interpreted by the emulator 206 in the LED module 202 as the new signal CUT LED Power 50% causing the LED driver 212 to reduce the power to the LED source 214 by 50%. The existing mechanical function signal “Filter Out” that was sent from the HOST (TEL ACT8), e.g., host controller 204, may now be interpreted by the emulator 206 in the LED module 202 as the new signal “Filter Out” causing any previous 50% reductions from a “Filter In” command to be undone, i.e., power is brought back to 100% or optionally current power to the LED module 202 may be doubled.

The existing mechanical function signal “Diaphragm Open” that was sent from the HOST (TEL ACT8), e.g., host controller 204, may now be interpreted by the emulator 206 in the LED module 202 as the new signal LED Intensity Up causing the power to be increased by a small predetermined increment amount by the LED driver 212 to the LED light source 214. The existing mechanical function signal “Diaphragm Close” that was sent from the HOST (TEL ACTS), e.g., host controller 204 may now be interpreted by the emulator 206 in the LED module 202 as the new signal LED Intensity Down causing the power to be decreased by a small predetermined increment amount by the LED driver 212 to the LED light source 214.

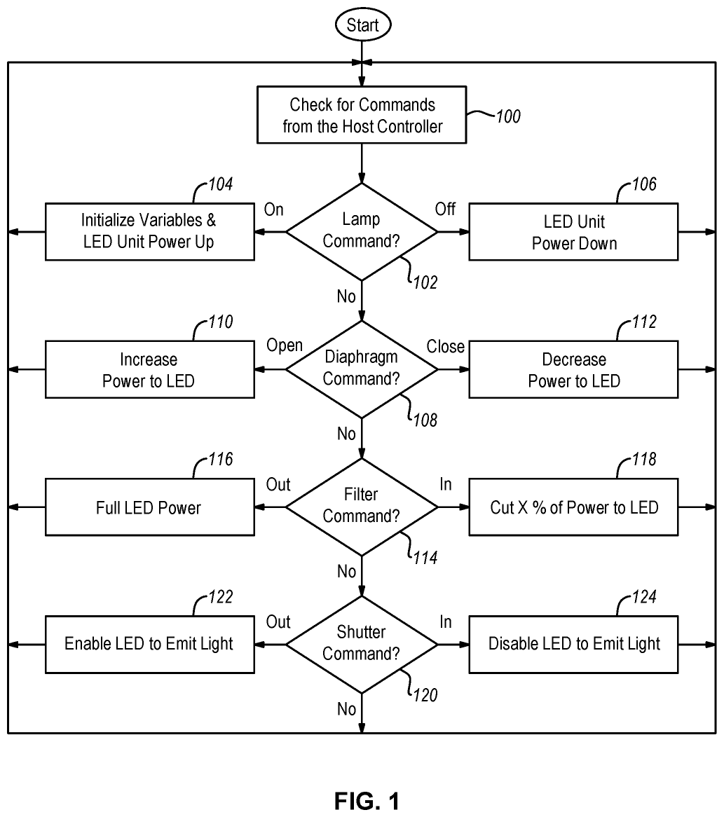

Referring to FIG. 1, a flowchart of a process that may be used to practice some embodiments of the invention is illustrated. The emulator 206 may have code, software or firmware performing the illustrated process stored at any desired location. As a non-limiting example, the software or firmware may be embedded in a microcontroller or any type of ROM in communication with the microcontroller that may be part of the emulator 206.

The emulator 206 may receive commands from the host controller 204 using any desired means and at any desired time during the process. (Step 100) While FIG. 1 shows step 100 has happening only once in the beginning of the process, the emulator 206 may check for commands from the host controller one or more times during the process or whenever desired. As non-limiting examples, the emulator 206 may check one or more discreet signal lines from the host controller 204 to determine if any commands have been issued and if so, what command(s) were issued. In another embodiment, the host controller 204 may push one or more commands along a data path to the emulator 206. In another embodiment, the emulator 206 may pull one or more commands along a data path from the host controller 204. Once the emulator 206 receives a command from the host controller 204, the emulator 206 may then determine which command was issued.

If the received command is a “Lamp On” Command (Step 102), the emulator 206 may initialize various variables to start the process and either turn on the LED light source 214 or make sure the LED light source 214 is in operating condition and ready to be turned on (Step 104). The emulator 206 may then send a signal back to the host controller 204 that the lamp is On if the LED light source 214 tested as being ready and operational. It should be appreciated that the replaced mercury lamp is not actually turned on due to this command as the lamp has been removed from the LED WEE apparatus 200.

If the received command is a “Lamp Off” command (Step 102), the emulator 206 may turn the LED light source 214 off and send a signal to the host controller 204 that the Lamp is off (Step 106). It should be appreciated that the replaced mercury lamp is not actually turned off due to this command as the lamp has been removed from the LED WEE apparatus 200.

If the received command is a “Diaphragm Open” command (Step 108), the emulator 206 may cause the LED Driver 212 to increase the power to the LED light source 214 by some predetermined incremental amount thereby incrementally increasing the intensity of the LED light source 214 up to a predetermined maximum amount (Step 110). It should be appreciated that no diaphragm is actually used due to this command.

If the received command is a “Diaphragm Close” command (Step 108), the emulator 206 may cause the LED Driver 212 to decrease the power to the LED light source 214 by some predetermined incremental amount thereby incrementally decreasing the intensity of the LED light source 214 (Step 112). It should be appreciated that no diaphragm is actually used due to this command.

If the received command is a “Filter In” command (Step 114) and there is not already an active “Filter In” command being performed, the emulator 206 may cause the LED driver 212 to decrease the power to the LED light source 214 by some predetermined amount, such as, as a non-limiting example, by 50%, thereby decreasing the intensity of the LED light source 214 (Step 118). If there is already an active “Filter In” command being performed, any future “Filter In” commands may either preferably be ignored or optionally may reduce the power by another 50%. It should be appreciated that no filter is actually used due to this command. In other embodiments, a “Filter In” command may reduce the power by either 5%, 10%, 25%, 33%, 50% or 75% as desired or any other desired amount.

If the received command is a “Filter Out” command (Step 114) and there is an active “Filter In” command being performed, the emulator 206 may cause the LED Driver 212 to increase the power to the LED light source 214 by some predetermined amount, such as, as a non-limiting example, by 100%, thereby removing the previous 50% reduction, thereby increasing the intensity of the LED light source 214 (Step 116). If there is not an active “Filter In” command being performed, any future “Filter Out” commands may either preferably be ignored or optionally may increase the power by 100% up to a maximum predetermined safety power limit. It should be appreciated that no filter is actually used due to this command.

If the received command is a “Shutter Open” command (Step 120), the emulator 206 may enable the LED light source 214 to emit light, possibly by applying power to the LED light source 214 (Step 122). It should be appreciated that no shutter is actually used due to this command.

If the received command is a “Shutter Close” command (Step 120), the emulator 206 may disable the LED light source 214 from emitting light, possibly by reducing the power to the LED light source 214 to zero (Step 124). It should be appreciated that no shutter is actually used due to this command.

During the process illustrated in FIG. 1, the host controller 204 may read the intensity of the light from the LED light source 214 using the host sensor 220 to determine if more or less light energy is needed and send additional “Diaphragm Open,” “Diaphragm Close,” “Filter Out,” “Filter In,” Shutter Open,” and/or “Shutter Close” commands as needed to achieve the desired light intensity from the LED light source 214.

In an example embodiment, the process may be performed according to the following software, firmware or code stored on the LED module 202 and electronically accessible by the emulator 206:

The process may start by initializing various variables and clearing flags used in previous processes:

1
2 ;LED_DUV_DAC5a, DUV specific production program, 02/13,reverse shutter(b.6) logic at
lin23,58,63,127,140,155,179,202
3 ;Filter option enabled,
4 ;Setup for DUV LEDs
5 ;Uses 28x2,
6 ;
7 ;Symbols
8 symbol i2c_dac = %10011000 ;DAC address is $98
9 Let dirsA = %10111 ;A0,A1,A2,A4 =Outputs
10 Let dirsB = %11100000 ;B7,B6,B5 =Outputs
11 Let dirsC = %01011110 ;C6,C4,C3,C2,C1=Outputs
12 hi2csetup i2cmaster, i2c_dac, i2cslow, i2cbyte ;DAC setup as slave at $98 address
13 Let b2 =0 ;Clear shutter/LED flag
14 let b3=0 ;clear filter flag
15 pullup %00011111 ;enable pullups on portB0-4 on 28X2
16
17

The process may power up the LED light source and display on the display 208 the time the LED light source has been used:

18 Begin: ;LED Unit power up
19
20 let pinB.5 =0 ;clears previous lamp Rdy command
21 let pinB.7 =0 ;clears previous lamp ON to track
22 ;let pinC.3 =0 ;clears previous lamp RDY to track
23 Let PinB.6 =0 ;Ensure shutter is closed
24 read 8, word w10 ;Previous min
25 read 12, word w12 ;previous Hrs
26 read 16,word w6 ;Previous source power setting
27 let w5=w6 ;Start DAC at previous saved setting
28 Pause 1000
29 serout A.4,N2400,(254,128,″LED Use;″,#w12,″ ″);Line2 Display saved use time
30 pause 1000
31 serout A.4,N2400,(254,148,″Mod,DUV 255,DAC4a ″);Line3, icRev-oledRev
32 pause 3000
33

The process may then track the power sequence, set initial power settings for the LED light source 214, establish normal operations and display the current power settings and the LED power settings on the display 208:

34 LEDP: ;Track power sequance, sets initial power and normal operations
35
36 serout A.4,N2400,(254,192,″LED Power;″,#w7,″ ″) ;Displays current LED pwr setting
line2
37 ;Temp check sequance
38 readtemp C.5, B1 ; Read the DS18B20 temperature
39 pause 10 ; Wait a while
40 serout A.4,N2400,(254,148,″LED Temp;″,#B1,″c ″);Text on 2nd line
41 If B1>40 then
42 serout A.4,N2400,(254,148,″LED is at Over-Temp ″) ;Text on 2nd line
43 let pinC.6 =0 ;LED OVT error to track
44 else let pinC.6=1
45 endif
46

The process may then check to verify that the lamp is ready to track:

47 ;TRKINIT
48 if pinB.2 =0 then ;checks for filter signal from track
49 let pinC.1 =0 ;filter active to track
50 ;serout A.4,N2400,(254,128,″Filter IN ″);Line3, light is not filtered
51 pause 100 ;give track time to see filter is INpause 100
52 else
53 let pinC.1=1 ;Filter not active to track
54 ;serout A.4,N2400,(254,128,″Filter OUT ″);Line3, light is filtered
55 pause 100 ;give track to see filter is NOT IN
56 end if
57 if pinB.1 =0 then ;Shutter active from track
58 let pinB.6 =1 ;OPEN E-shutter
59 let pinC.2 =1 ;Shutter active to track
60 ;serout A.4,N2400,(254,192,″Shutter OPEN ″);Line3, icRev-oledRev
61 else
62 let pinC.2 =0 ;Shutter not active to track
63 let pinB.6 =0 ;CLOSE E-shutter
64 let pinC.2=0 ;Shutter not active to track
65 ;serout A.4,N2400,(254,192,″Shutter Close ″);Line3, icRev-oledRev
66 ;let b2=0 ;Shutter/LED is not radiating flag
67 end if
68 ;Timer Count
69 if w10>3600 then ;Elapsed Seconds
70 let w12=w12+1 ;Elapsed hours
71 write 12,b24,b25 ;Save hrs (w12) to eeprom
72 let w10=0
73 end if
74 serout A.4,N2400,(254,128,″LED Hours;″,#w12,″ ″);Total time display line4
75 pause 10
76 ;Lamp on
77 If pinB.0 =0 then ;lamp on comand from track NEEDS A FLAG?
78 Pause 20 ;Wait lamp to turn on
79 let pinB.7 =1 ;lamp ON simulated confirm to track
80 Pause 20 ;wait lamp to warm up
81 Let pinB.5=1 ;Lamp ready to track
82 ;DAC levels w5
83 let b22 = b10 ;write DAC power W5 to W11 (b22&B23)
84 let w11 = b22 * 16 ;Shifts register over 4bits allowing for LSB and MSB
85 HI2cOut (b23,b22) ;b22 is any input variable 0-256)
86 let pinC.3 =1 ;lamp RDY simulated confirm to track
87 let w7=w5*1 ;i-Line calibration number if needed
88 ;let w7=w5*1 ;DUV calibration number
89 goto NORMOP
90 else
91 let pinB.7=0 ;lamp is not ON to the track
92 ;DAC levels w5
93 let b22 = 0 ;Zero out DAC power to W11
94 let w11 = b22 * 16 ;Shifts register over 4bits allowing for LSB and MSB
95 HI2cOut (b23,b22) ;b22 is any input variable 0-256)
96 let pinB.5=0 ;lamp not RDY to track
97 goto LEDP
98 end if

After the initial setup is completed, the software may start the emulation process and display the current LED power settings on the display 208:

99 NORMOP:
100 ;serout A.4,N2400,(254,128,″LED Dose: ″,#timer,″ sec ″);Real time display line4
101 serout A.4,N2400,(254,192,″LED Power;″,#w7,″ ″) ;Displays current LED pwr setting
line2
102 pause 10
103 ;DAC levels w5
104 let b22 = b10 ;write DAC power to W11
105 let w11 = b22 * 16 ;Shifts register over 4bits allowing for LSB and MSB
106 HI2cOut (b23,b22) ;b22 is any input variable 0-256
107 if pinB.3 =0 and pinB.1 =0 then ;Inc ON, Shutter OPEN
108 goto PWRINC ;Power increase sub routine
109 end if
110 if pinB.4 =0 and pinB.1 =0 then ;DEC ON, Shutter OPEN
111 goto PWRDEC ;Power decrease sub routine
112 end if
113 if pinB.2 =0 and pinB.1 =0 then ;Filter in B.2, Shutter open B.1,
114 goto FLTRON ;Filter subroutine
115 endif
116 ;FLTROFF:
117 let pinC.1=1 ;Filter not active to track
118 clearbit b3,0 ;clears power filtered bit
119 let w5=w6
120 let w7=w5*1 ;i-Line calibration number if needed
121 ;let w7=w5*1 ;DUV calibration number
122 ;write 16,b12,b13 ;Saves adjusted value w6 to EPROM
123 If pinB.1 =0 then ;Shutter open comand from track
124 goto SHTRON
125 endif
126 if pinB.1 =1 then ;No shutter open comm from track
127 let pinB.6=0 ;Electronic shutter close
128 let pinC.2 =0 ;shutter blocking to track
129 let b2=0
130 serout A.4,N2400,(254,212,″LED is Ready ″) ;LED is OFF line1
131 settimer off
132 write 8, b20,b21
133 let w10=w10+timer ;Dont zero timer, let it pickup
134 let timer=0
135 endif
136 goto LEDP
137

The following subroutine may be called when the host controller 204 sends a “Shutter On” or “Shutter OFF” command to the emulator 206 and the emulator 206 disables or enables the LED light source 214 from emitting light to a workpiece:

138 SHTRON:
139 settimer t1s_4 ;Timer counts at 4mhz
140 let pinB.6=1 ;Electronic shutter open driver
141 let pinC.2=1 ;shutter not blocking to track
142 ;let b2=1 ;Shutter flag
143 pause 500
144 serout A.4,N2400,(254,128,″LED Dose;″,#timer,″sec ″);Real time display line4
145 pause 10
146 ;let w10 =timer ;save time to eeprom?
147 ;How deal with doses longer then 60sec???
148 ;pause 500
149 ;serout A.4,N2400,(254,192,″LED Power: ″,#w5,″mW ″) ;Displays current LED pwr
setting line2
150 serout A.4,N2400,(254,212,″LED is Radiating ″) ;LED is ON line1
151 goto NORMOP
152

The following subroutine may be called when the host controller 204 sends a “Diaphragm Open” command to the emulator 206 and the emulator 206, via the LED driver 212, increases the power to the LED light source 214:

153 PWRINC:
154 settimer t1s_4 ;Timer counts at 4mhz
155 let pinB.6=1 ;Electronic shutter open driver
156 let pinC.2 =1 ;shutter not blocking to track
157 if w5<191 then ;i-Line track increases LED pwr 191max
158 ;if w5<100 then ;DUV track increases LED pwr 100max
159 let w5=w6+1
160 let w6=w5
161 let w7=w5*1 ;i-Line calibration number if needed
162 ;let w7=w5*1 ;DUV calibration number
163 serout A.4,N2400,(254,192,″LED Power:″,#w7,″ ″) ;Displays current LED pwr setting
line2
164 serout A.4,N2400,(254,212,″LED is Radiating ″) ;LED is ON line1
165 ;DAC levels w5
166 let b22 = b10 ;write DAC power to W11
167 let w11 = b22 * 16 ;Shifts register over 4bits allowing for LSB and MSB
168 HI2cOut (b23,b22) ;b22 is any input variable 0-255
169 endif
170 write 16,b12,b13
171 if w5>220 then ;DUV track Max LED pwr
172 ;if w5>100 then ;i-Line track Max LED pwr 100
173 serout A.4,N2400,(254,192,″LED Power is at max ″) ;Displays max power warning line2
174 endif
175 goto NORMOP
176

The following subroutine may be called when the host controller 204 sends a “Diaphragm Close” command to the emulator 206 and the emulator 206, via the LED driver 212, decreases the power to the LED light source 214:

177 PWRDEC:
178 settimer t1s_4 ;Timer counts at 4mhz
179 let pinB.6=1 ;Electronic shutter open driver
180 let pinC.2 =1 ;shutter not blocking to track
181 if w5>2 then ;Track decreases LED pwr 2 min
182 let w5=w6-1
183 let w6=w5
184 let w7=w5*1 ;i-Line calibration number
185 ;let w7=w5*1 ;DUV calibration number
186 serout A.4,N2400,(254,192,″LED Power:″,#w7,″ ″) ;Displays current LED pwr setting
line2
187 serout A.4,N2400,(254,212,″LED is Radiating ″) ;LED is ON line1
188 ;DAC levels w5
189 let b22 = b10 ;write DAC power to W11
190 let w11 = b22 * 16 ;Shifts register over 4bits allowing for LSB and MSB
191 HI2cOut (b23,b22) ;b22 is any input variable 0-255
192 endif
193 write 16,b12,b13
194 ;write 16,b10,b11
195 if w5<2 then ;Track decreases LED pwr
196 serout A.4,N2400,(254,192,″LED Power is at min ″) ;Displays min power warning line2
197 endif
198 goto NORMOP
199

The following subroutine may be called when the host controller 204 sends a “Filter On” or “Filter Off” command to the emulator 206 and the emulator 206, via the LED driver 212, decreases the power to the LED light source 214 by 50% and displays “LED Radiating @ 50%” to the Display 208 or restores (doubles) the power to the LED light source 214:

200 FLTRON: ;Filter in sequence
201 ;settimer t1s_4 ;Timer counts at 4mhz
202 let pinB.6=0 ;Electronic shutter open driver
203 let pinC.2 =1 ;shutter not blocking to track
204 let pinC.1 =0 ;filter active to track
205 if b3 bit 0 clear then
206 let w4=w6/2 ;cut power by50%
207 let w5=w4 ;send cut power to pwm value
208 setbit b3,0 ;sets power filtered bit
209 serout A.4,N2400,(254,212,″LED Radiating @ 50% ″);Displays filter status line4
210 endif
211 goto NORMOP

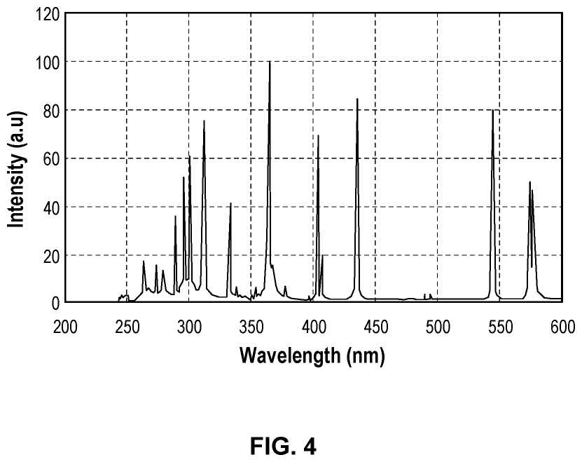

FIG. 4 is a graphical representation of intensity versus wavelength of a conventional mercury (Hg) lamp.

Referring to FIG. 4, an output of a conventional mercury lamp produces broad spectrum energy having wavelength in range from 200 nm to 600 nm at varying intensity levels. The graph shows a spectral distribution of a conventional mercury (Hg) lamp source used in semiconductor lithography exposure processes. Referring to FIG. 5, it is shown that light from an LED may range between about 255 nm to about 415 nm or greater. In standard lithography, curing happens in a narrow emission range and the remainder of the spectral energy output is unneeded and are potentially harmful UV-C and infrared emissions. LED WEE apparatuses 200 described herein narrow the emission range as compared to conventional mercury lamps. The LED curing efficiently converts about twenty percent to about forty percent of the input energy into useable UV light with no harmful UVC, UVB or infrared exposure. The efficiency further translates into about an eighty percent power and heat savings over conventional mercury (Hg) lamps.

In one embodiment, an LED WEE apparatus 200 is configured to emit energy having a wavelength in a range from about 365 nm to about the 415 nm ranges. The wavelength of energy emitted by the LED light source 214 is stable and has a precise wavelength of light at a much lower energy cost as compared to a mercury (Hg) lamp light source. Moreover, the mercury (Hg) lamp light sources of the related art require a larger footprint for power sources and control mechanisms as compared to the embodiments described herein. The apparatus as described herein has a footprint of 6,600 cc while the apparatus of the related art has a footprint of 60,000 cc. Moreover, use of mercury (Hg) lamps are being phased out by various local and international regulatory agencies. Some regulations have been revised since it has been economically or technologically prohibitive to phase out mercury (Hg) lamps in various industries.

In one embodiment, the direct replacement apparatus described herein is for a LED wafer edge exposure (WEE) apparatus 200 and processes. The WEE process requires very specific wavelengths of light to initiate the photo-resist cross linking process. The two typical wavelengths of light used by these processes are 365 nm (i-Line) and 248 nm (DUV). In one embodiment, the LED UV light sources include LEDs configured for the specific wavelength of light required for the process photoresist material.

In one embodiment, the wafer edge exposure (WEE) LED light source 214 is an innovative cost-effective upgrade to the inefficient mercury light sources. One innovation that makes this product possible is its use of state of the art monochromatic DUV LED technology. For generations WEE processes have used short lived inefficient “Broad” spectrum mercury light sources, while the majority of the “WEE process” only requires light within a very narrow spectral range, with the remainder of the output energy resulting in extraneous light and heat emissions. The LED light source 214 provides light only within the extremely narrow band of spectral emissions required for the DUV exposure process, thereby being far more efficient in electrical usage.

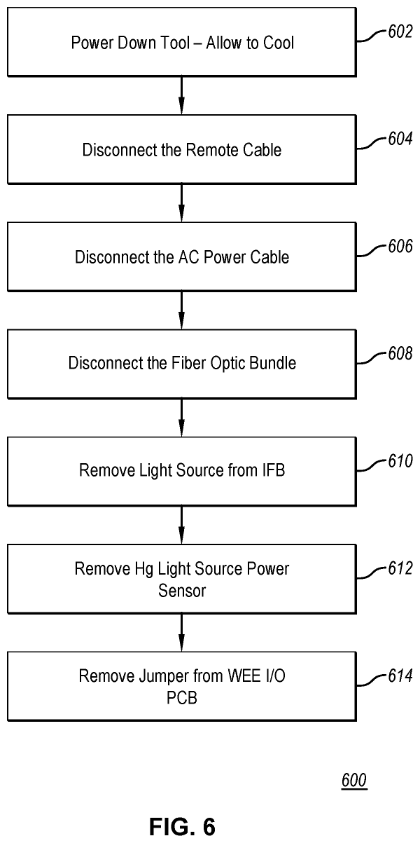

FIG. 6 illustrates an exemplary flowchart for removal of an existing light source according to an embodiment of the invention.

Referring to FIG. 6, the process 600 is directed towards removal of an existing lamp source, e.g., a mercury vapor lamp or other lamp source, in an existing WEE apparatus. The lamp unit may be powered down and cooled before removing. (Step 602) The process 600 further includes disconnecting the host I/O connection, e.g., DB25 Host I/O cable, or the like (step 604). The process 600 further includes disconnecting the power cable, e.g., disconnect 200 VAC power cable or the like (step 606). Next, the fiber optic bundle is disconnected (step 608). Remove the light source unit from the tool (step 610). Remove light source sensor from the processing area, e.g., wafer processing area (step 612). Remove electrical connections (step 614). In a preferred embodiment, the electrical connections include a green Jumper J2 from the WEE I/O PCB typically located around the area of the power sensor board BNC connector. The process for removing the old mercury lamp unit is now complete.

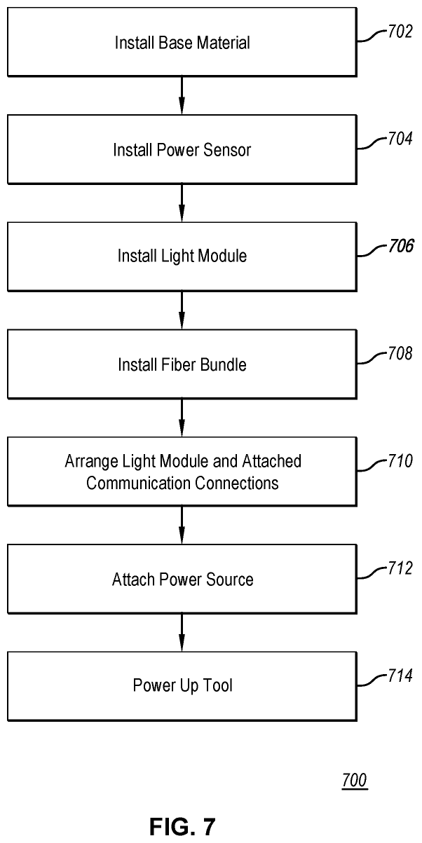

FIG. 7 illustrates an exemplary flowchart for installing an LED module 202 in an embodiment of the invention.

Referring to FIG. 7, the process 700 is directed towards installation of an LED module 202 as described herein into the location near where the previous mercury lamp was removed. The process 700 includes installation of base materials into the unit with the removed light source (step 702). In a preferred embodiment, the base materials include a base plate arranged where the original mercury light source was removed from. The base plate may include a plastic or an acrylic material. The installation further includes an orientation of the base plate and securing the base plate with one or more securing mechanisms. In a preferred embodiment, four 5×45 mm bolts and washer and nuts are used to secure the base plate. The base plate is configured to allow for mounting the smaller LED module 202 in the same location as the larger now removed mercury lamp light source.

Next a power sensor is installed into the processing area (step 704). The power sensor is preferably compatible with measuring light emitted by an LED. The power sensor may be a gallium arsenide photo-diode that quantifies the light energy produced by lower wavelengths of light. The power sensor is configured to optimally quantify the single wavelength of light emitted by the LED, into a signal recognizable by the existing host controller 204. The LED module 202 is installed into the system (step 706). The LED module 202 is any light module as described herein, e.g., LED light module. The LED module 202 is installed on the base plate by attaching four bolts. Next, a fiber bundle is attached to the LED light module (step 708). The fiber bundle includes two knurled rings for connecting the fiber bundle to both the LED light source and host tool. Arrange light module and attached communication connections (step 710). In a preferred embodiment, arrangement of the LED module 202 includes orientating the LED module 202 in the WEE compartment, so the display faces the compartment door, and the LED module door vents face the IFB heat exhaust opening. Attaching the communication connections includes attaching the DB25 Remote Cable. The power source 210 is attached to the installed unit (step 712). In a preferred embodiment, the power source 210 is attached by attaching an AC power cable and AC extension cables as needed. Next, the tool is powered up and new exposure power settings are configured (step 714). The power settings include increasing or decreasing the LED light source 214 output by translating the host tool's diaphragm movement commands in an analog signal by controlling the LED Driver 212 output.

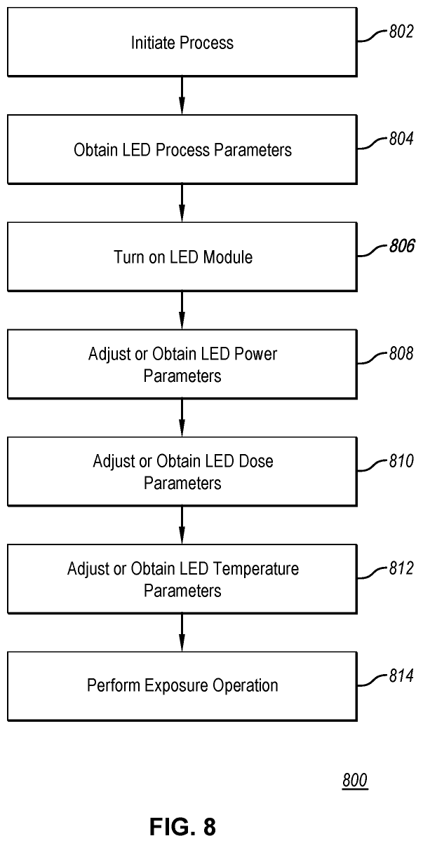

FIG. 8 illustrates an exemplary flowchart for using an apparatus according to an embodiment of the invention.

Referring to FIG. 8, the process 800 is directed towards using an apparatus as described herein so that when the LED module 202 is powered up for the first time, the LED WEE apparatus 200 sees it as a regular mercury light source.

The process 800 includes an LED module 202 initial process operation (step 802). The LED WEE apparatus 200 begins to issue commands to adjust the LED light emissions to match those specified by the LED WEE apparatus 200 process requirements.

Obtain LED process parameters (step 804). In step 804, the initial parameters are obtained by directly inputting into the apparatus or the LED WEE apparatus 200 may determine a desired recipe and read the desired recipe from a database having a plurality of stored recipes. For example, the initial parameters may be transferred from an old UV mercury lamp source and converted into a new LED WEE apparatus recipe. In one embodiment, this conversion of the old recipe into a new recipe is achieved by the LED emulator translating the host tool's recipe parameters into signals that the LED module can use to provide the results expected by the host tool. In other embodiments, new recipes for the LED WEE apparatus 200 may need to be determined using empirical methods.

Turn on the LED module (step 806). In step 806, the LED light source 214 is now emitting energy and UV light should be seen illuminating the DUV power sensor in the exposure process area.

Adjust the LED power (step 808). The power is adjusted by the host controller 204 by sending pulse commands to a mechanical diaphragm which either opens or closes as required. As there is no longer a mechanical diaphragm in the replacement LED module 202, the emulator 206 must use these pulse commands to increase or decrease an analog signal to the LED Driver 212, thereby increasing or decreasing the power to the LED light source 214, thereby increasing or decreasing a light intensity from the LED light source 214. The track's power feedback, consisting of a photodiode and host tool control system, may be used to obtain a desired light intensity from the LED light source 214.

Adjust the LED dose (step 810). In this step 810, the timer is counting up, this will display the length of time the LED has been on for that particular illumination cycle. When the module is idle, this will display the total accumulated time the LED has been radiating since it was installed. This LED dose can be obtained by the host tool control system and adjusted by the host tool's process requirements.

Adjust the LED temperature (step 812). In this step 812, the LED temperature will slowly increase, the longer the LED is continuously illuminating. If the number exceeds a predetermined threshold, e.g., 40c (nominal is 25c), both the tool and the LED light source 214 will stop operations for “WEE Over temp” alarms. Optionally, the processing may continue after the LED temperature has cooled down to below 40c.

Perform exposure operation (step 814). In this step 814, the exposure of the UV lithography step is performed. The process is repeated for additional operations.

Further in operation, the emulator 206 is configured to interpret the discrete I/O signals utilized by the host controller 204 to control a mercury (Hg) vapor light source, and convert the signals into signals that can be used by the LED module 202 and LED WEE apparatus 200 as described in embodiments herein.

Optical energy measurement of LED power is typically measured using either spectrometers or spectral radiometers. Due to the broad spectral response of silicon photodiodes typically used on ACT8 to measure energy levels of multiple light sources, Host tool's measurement of a monochromatic DUV light source will indicate power levels well below what is commonly expected during operations with a multi spectral mercury light source. In some embodiments, a provided onboard light sensor may have been designed to give consistent power readings that will minimize the power measurement error inherent with silicon photo diodes. The LED light source 214 is incredibly stable, and when paired with the appropriate power sensor the LED light source 214 will offer a stable and reliable addition to the LED WEE apparatus 200.

In one embodiment, the process uses an empirical process verification based on Periodic Dose to Clear—(DTC) tests to ensure power levels displayed by the LED WEE apparatus 200 directly correlate to expected process results.

Particular example implementations of the subject matter have been described. As will be apparent to those skilled in the art, other implementations, alterations, and permutations of the particular implementations are considered to be within the scope of the disclosure and the following claims. Features of the various implementations are also combinable. While operations are depicted in the drawings or claims in a particular order, this should not be understood as requiring that such operations be performed in the particular order shown or in sequential order, or that all illustrated operations be performed (some operations may be considered optional), to achieve desirable results.

While this disclosure contains many specific implementation details, these should not be construed as limitations on the scope of any invention or on the scope of what may be claimed, but rather as descriptions of features that may be specific to particular implementations of particular inventions. Certain features that are described in the context of separate implementations can also be implemented, in combination, in a single implementation.

Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Accordingly, the previously described example implementations do not necessarily define or constrain this disclosure. Other changes, substitutions, and alterations are also possible within the scope of this disclosure.

To avoid unnecessarily obscuring the present disclosure, the preceding description may omit a number of known structures and devices. This omission is not to be construed as a limitation of the scope of the claims. Specific details are set forth to provide an understanding of the present disclosure. It should however be appreciated that the present disclosure may be practiced in a variety of ways beyond the specific detail set forth herein.

Also, while the figures, charts, drawings, photographs, may have been discussed and illustrated in relation to a particular sequence of events, it should be appreciated that changes, additions, and omissions to this sequence can occur without materially affecting the operation of the disclosed embodiments, configuration, and aspects. A number of variations and modifications of the disclosure can be used. It would be possible to provide for some features of the disclosure without providing others.

Moreover, though the description has included a description of one or more aspects, implementations, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges, or steps to those claimed, whether or not such alternate, interchangeable and/or equivalent structures, functions, ranges or steps are disclosed herein, and without intending to publicly dedicate any patentable subject matter.

1. A method for retrofitting an existing high energy edge exposure unit, comprising:
removing an existing high energy light source from the existing high energy edge exposure unit; and
arranging a low energy light source in the existing high energy edge exposure unit.

2. The method of claim 1, wherein the high energy light source comprises a mercury vapor light source.

3. The method of claim 1, wherein the low energy source comprises a light emitting diode (LED) light source.

4. The method of claim 1, wherein the LED light source is configured to emit energy having a wavelength in a range from about 255 nm to about 400 nm range.

5. The method of claim 4, wherein the wavelength is in a range from about 340 nm to about 380 nm range.

6. The method of claim 5, wherein the wavelength is in a range from about 360 nm to about 370 nm range.

7. A method of operating a retrofit high energy edge exposure unit for edge exposure, comprising:
proving a low energy retrofit edge exposure unit;
receiving a workpiece covered by a photosensitive layer; and
exposing an edge portion of the photosensitive layer to radiation generated by the low energy retrofit edge exposure unit.

8. The method of claim 7, wherein the radiation generated by the low energy retrofit edge exposure unit is emitted from a light emitting diode (LED).

9. An edge-exposure tool, comprising:
a workpiece table configured to support a workpiece covered by a photosensitive layer, and
a retrofit edge exposure light source configured to radiate the photosensitive layer.

10.-40. (canceled)
